(19) United States
(12) Patent Application Publication
(10) Pub. No.: US 2009/0055127 A1
(43) Pub. Date: Feb. 26, 2009

(54) METHOD FOR GAIN ERROR ESTIMATION FOR AN ANALOG-TO-DIGITAL CONVERTER

(75) Inventors: Yu-Hsuan TU, Tainan City (TW); Kang-Wei HSUEH, Hsinchu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/121,219

(22) Filed: May 15, 2008

Related U.S. Application Data
(60) Provisional application No. 60/956,954, filed on Aug. 21, 2007.

(51) Int. Cl. G01R 15/00; H03M 1/12

(52) U.S. Cl. 702/179; 341/155

(57) ABSTRACT

The invention provides a method for gain error estimation for an analog-to-digital converter. In one embodiment, the analog-to-digital converter comprises a plurality of stages. First, a series of correction numbers applied to a target stage selected from the stages are correlated with a series of first values calculated according to digital output values of the stages to generate a series of gain error estimates. Every first number of the series of gain error estimates is then averaged to obtain a series of second values. A second number of the series of second values is then averaged to obtain a gain error of the target stage.

### CROSS REFERENCE TO RELATED APPLICATIONS

This application claims the benefit of U.S. Provisional Application No. 60/956,954, filed on Aug. 21, 2007, the entirety of which is incorporated by reference herein.

### BACKGROUND OF THE INVENTION

1. Field of the Invention

The invention relates to analog-to-digital converters, and more particularly to the gain error estimation of analog-to-digital converters.

2. Description of the Related Art

Referring to FIG. 1, a block diagram of a pipelined analog-to-digital converter (ADC) 100 according to the prior art is shown. The pipelined ADC 100 converts an analog input signal Vᵢₙ from analog to digital to obtain a digital conversion value Dₒᵤₜ as an output thereof. The pipelined ADC 100 comprises M stages 101˜10M connected in series and a gain error correction module 110. The first stage 101 derives a digital output value dₒ₁ from the analog input signal Vᵢₙ and generates a residual signal R₁ indicating a difference between the analog input signal Vᵢₙ and the digital output value dol. The stages 102˜110M then receive residual signals R₁˜R_{M-1} of prior stages 101˜10(M−1) thereof as input signals and respectively derive digital output values dₒ₂˜d_{oM} from the input signals thereof. Accordingly, the stages 102˜110(M−1) also generate residual signals R₂˜R_{M-1}, indicating differences between the input signals R₁˜R_{M-2} thereof and the digital output values dₒ₂˜d_{o(M-1)} thereof. The gain error correction module 110 then calculates the digital conversion value Dₒᵤₜ according to the digital output values dₒ₁˜d_{oM} of the stages 101˜10M as the output signal of the pipelined ADC 100.

Before a residual signal of a current stage is output to a subsequent stage as an input, the residual signal is amplified with an amplifier according to a predetermined gain of the current stage. Referring to FIG. 2A a block diagram of a k-th stage 250 according to the prior art is shown. The k-th stage 250 comprises a sub analog-to-digital converter 252, a sub digital-to-analog converter 254, a summing stage 256, and an amplifier 258. The sub ADC 252 first converts a residual signal Rₖ₋₁ of a (k−1)-th stage prior to the k-th stage 250 from analog to digital to obtain a digital output value dₒₖ. The sub DAC 254 then converts the digital output value dₒₖ from digital back to analog to obtain a signal Xₖ. The summing stage 256 then subtracts the signal Xₖ from the residual signal Rₖ₋₁ to obtain a signal Yₖ, representing a difference between the input signal Rₖ₋₁ and the digital output value dₒₖ. The amplifier 258 then amplifies the signal Yₖ according to a predetermined gain G to obtain a residual signal Rₖ of the current stage 250.

Although in the methodology, the predetermined gain G is presumed constant, the actual gain of the amplifier 258 deviates from the predetermined gain G with temperature changes and circuit manufacture variations. The difference between the actual gain and the predetermined gain is referred to as a gain error of a stage. When the actual gain of the current stage deviates from the predetermined gain, a gain error occurs, and the residual signal output by the current stage has an amplitude error, which induces errors in digital output values of subsequent stages. The gain error correction module 110 therefore must estimate a gain error and calibrate the digital conversion value Dₒᵤₜ according to the gain error. Otherwise, accuracy and resolution of the digital conversion value Dₒᵤₜ decreases.

In FIG. 1, the gain error correction module 110 applies a series of correction numbers S to the first stage 101 for estimation of the gain error of the first stage 101. Referring to FIG. 2B, a block diagram of a target stage 200 for gain error estimation according to the prior art is shown. In addition to a sub ADC 202, a sub DAC 204, a summing stage 206, and an amplifier 208, the target stage 200 further includes an adder 212 adding a correction number S and a stage output value dₒ₁ to obtain a signal Z₁. In addition, because the target stage 250 is the first stage 101 of the ADC 100, the target stage 250 comprises a sample and hold (S/H) circuit 214 for sampling input signals and holding the samples. The sub DAC 204 then converts the signal Z₁ from digital to analog to obtain a signal X₁, the summing stage 206 then subtracts the signal X₁ from the input signal Vᵢₙ to obtain a signal Y₁, and the amplifier 208 amplifies the signal Y₁ to obtain a residual signal R₁ of the target stage 200. Therefore, the residual signal R₁ of the target stage 101 and digital output values dₒ₂˜d_{oM} of the subsequent stages 102˜10M change with the correction number S.

As the digital output values dₒ₂˜d_{oM} change with the correction number S, the gain error correction module 110 estimates a gain error of the target stage 101 according to the digital output values dₒ₂˜d_{oM} and the correction number S. In reference to FIG. 1 and FIG. 2B, the following equation (1) is given:

(Vᵢₙ−dₒ₁−s)G^{M-1}(1+ε)=dₒ₂G^{M-2}+dₒ₃G^{M-3}+ . . . +d_{o(M-1)}G+d_{oM}; (1)

wherein Vᵢₙ is the input signal of the target stage 101, G is predetermined gains of stages 101˜10M, M is a number of stages, s is the correction number applied to the target stage, and ε is a gain error of the target stage 101. Meanwhile, equation (2) is derived from equation (1) as follows:

Vᵢₙ+ε·Vᵢₙ−ε·dₒ₁−ε·s=(dₒ₁+s)+dₒ₂G⁻¹+dₒ₃G⁻²+ . . . d_{oM}G^{-(M-1)}. (2)

If equation (2) is divided by the correction number s and averaged over N samples, the following equation (3) is obtained:

$$- ɛ = \frac{1}{N} {\sum }_{n = 1}^{N} \frac{\begin{matrix}{d}_{o 1} [ n ] + s [ n ] + {d}_{o 2} [ n ] \cdot {G}^{- 1} + \\ {d}_{o 3} [ n ] \cdot {G}^{- 2} + … + {d}_{oM} [ n ] \cdot {G}^{- ( M - 1 )}\end{matrix}}{s [ n ]} = \frac{1}{N} {\sum }_{n = 1}^{N} \frac{u [ n ]}{s [ n ]} = \frac{1}{N} {\sum }_{n = 1}^{N} v [ n ] \qquad ( 3 )$$

The gain error correction module 110 can average a large amount of gain error estimates v[n] to obtain the gain error ε of the target stage 101 according to the equation (3) as

$$\frac{1}{N} {\sum }_{n = 1}^{N} \frac{{V}_{in}}{s [ n ]} and \frac{1}{N} {\sum }_{n = 1}^{N} \frac{{d}_{o 1} [ n ]}{s [ n ]}$$

are equal to zero when the number N of samples is large enough.

Thus, according to the equation (3), the gain error correction module 110 first calculates gain error estimates v[n] corresponding to each sample index n and then averages a large amount of the gain error estimates v[n] to obtain a gain error of the target stage 101. To increase the effective number of bits (ENOB) of the digital conversion value Dₒᵤₜ, the number N of the averaged gain error estimates v[n] must be large enough for the resolution of the gain error ε to remain higher than a tolerable threshold. The gain error correction module 110 therefore requires a great memory space to store the gain error estimates v[n]. The great memory space occupied by the gain error estimates v[n], however, increases costs of the pipelined ADC 100. Thus, a method for gain error estimation for a pipelined analog-to-digital converter with reduced memory space requirement is desired.

### BRIEF SUMMARY OF THE INVENTION

The invention provides a method for gain error estimation for an analog-to-digital converter. In one embodiment, the analog-to-digital converter comprises a plurality of stages. First, a series of correction numbers applied to a target stage selected from the stages are correlated with a series of first values calculated according to digital output values of the stages to generate a series of gain error estimates. Every first number of the series of gain error estimates is then averaged to obtain a series of second values. A second number of the second values are then averaged to obtain a series of gain error of the target stage.

The invention also provides an analog-to-digital converter. In one embodiment, the analog-to-digital converter comprises a plurality of stages and a gain error correction module. The stages respectively generate a series of digital output values, wherein one of the stages is selected as a target stage for gain error estimation and processed with a series of correction numbers. The gain error correction module then calculates a series of first values according to the digital output values of the stages, correlates the series of correction numbers with the series of first values to generate a series of gain error estimates, averages every first number of the gain error estimates to obtain a series of second values, and averages a second number of the second values to obtain a gain error of the target stage.

The invention also provides a method for gain error correction in an analog-to-digital converter. In one embodiment, the analog-to-digital converter receives an analog input signal and comprises a plurality of stages. First, a gain error of a target stage selected from the stages is estimated. A digital conversion value of the analog input signal is then derived from digital output values of the stages by multiplying the digital output values by a polynomial of the gain error.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a block diagram of a pipelined analog-to-digital converter according to the prior art;

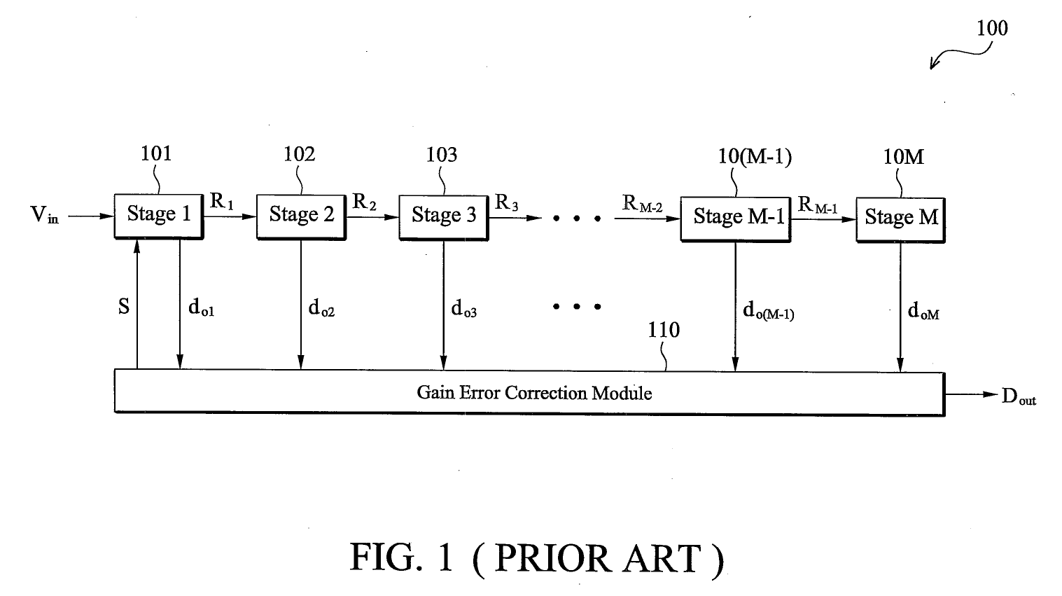

FIG. 2A is a block diagram of an ordinary stage of a pipelined ADC according to the prior art;

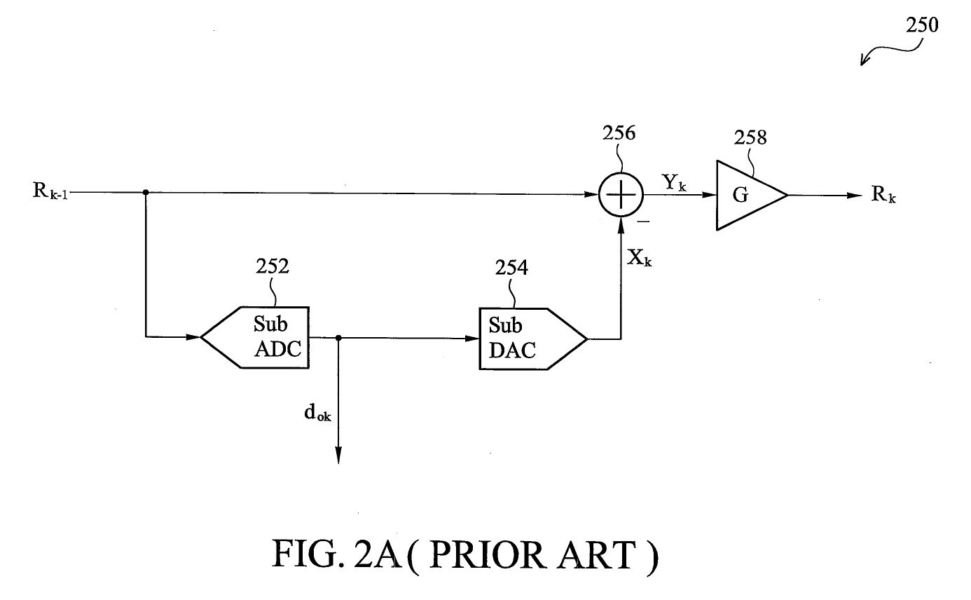

FIG. 2B is a block diagram of a target stage of a pipelined ADC for gain error estimation according to the prior art;

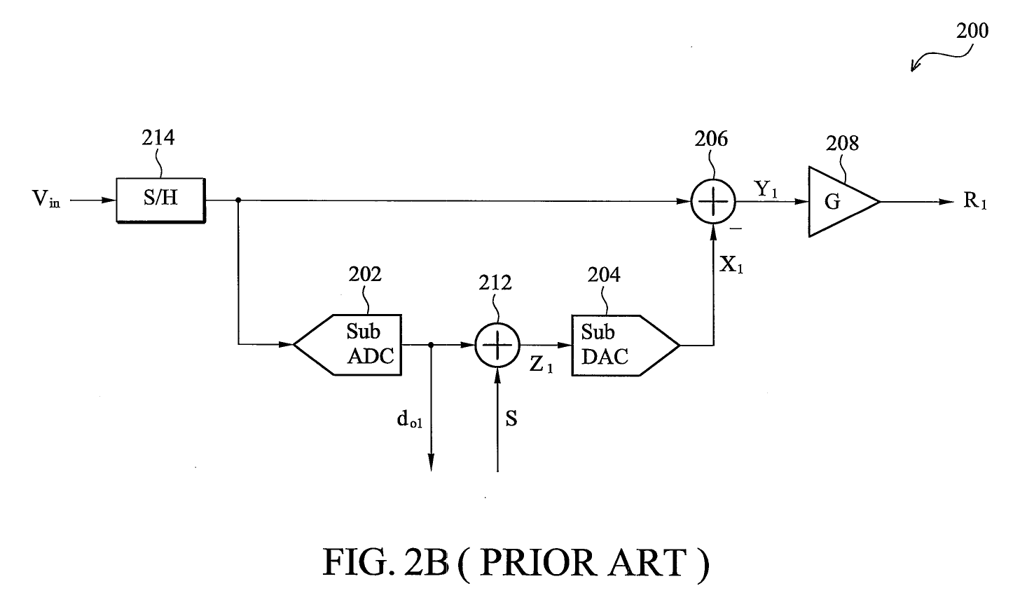

FIG. 3 is a schematic diagram of two memories of a pipelined ADC averaging gain error estimates with two phases according to the invention; and

FIG. 4 is a schematic diagram of a plurality of memories of a pipelined ADC averaging gain error estimates with a plurality of phases according to the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

For a conventional method for estimating a gain error of a target stage for a pipelined ADC, a gain error correction module first correlates a series of correction numbers s[n] applied to a target stage with a series of first values u[n] calculated according to digital output values of the stages to generate a series of gain error estimates v[n] corresponding to sample indexes n, as shown in the following equations:

$$\begin{matrix} v [ n ] = \frac{u [ n ]}{s [ n ]} ; & ( 4 ) \\ u [ n ] = {d}_{o 1} [ n ] + s [ n ] + {d}_{o 2} [ n ] \times {G}^{- 1} + {d}_{o 3} [ n ] \times {G}^{- 2} + … + {d}_{oM} [ n ] \times {G}^{- ( M - 1 )} ; & ( 5 )\end{matrix}$$

wherein n is a sample index, s[n] is the correction number, M is equal to a number of the stages, G is a predetermined gain of the stages, dₒ₁ is the digital output value of the target stage, and dₒ₂[n], dₒ₃[n], . . . , d_{oM}[n] are the digital output values of the stages subsequent to the target stage according to equation (3). The gain error control module then averages the series of gain error estimates v[n] to obtain a gain error ε of the target stage, as shown in the following equation:

$$ɛ = \frac{1}{N} {\sum }_{n = 1}^{N} v [ n ] , \qquad ( 6 )$$

wherein N is the number of gain error estimates being averaged. The conventional method, however, requires a large amount of memory space to store the gain error estimates v[n] being averaged. For example, generation of a gain error ε requires an average of 2²⁰ gain error estimates v[n], which requires 2²⁰ memory cells. The required memory space increases costs of the pipelined ADC.

A gain error correction module provided by the invention does not directly average the gain error estimates v[n]. Instead, average of the gain error estimates v[n] is divided into a plurality of average phases, and output values of a current average phase are then averaged in a subsequent average phase. Following multiple average phases, a gain error ε is finally generated by a final average phase. Although the gain error ε obtained according to the method provided by the invention is equal to the gain error obtained according to the conventional method, the memory space required by the method provided by the invention is reduced by a large amount in comparison with the conventional method.

For example, average of the gain error estimates v[n] may be divided into two average phases. A gain error correction module averages the gain error estimates in two average phases according to the following algorithm to calculate the gain error of the target stage:

$$ɛ = \frac{1}{Q} {\sum }_{{k}_{2} = 1}^{Q} {( \frac{1}{P} {\sum }_{n = 1}^{P} v [ n ] )}_{{k}_{2}} ; \qquad ( 7 )$$

wherein ε is the gain error of the target stage, v[n] is a gain error estimate corresponding to a sample index n, P is a predetermined first number, Q is a predetermined second number, and a product of the numbers P and Q is equal to the number N of gain error estimates v[n] to be averaged in equation (3). The gain error correction module first averages every first number P of the gain error estimates v[n] in the first average phase to obtain a series of average values

$$\frac{1}{P} {\sum }_{n = 1}^{P} v [ n ] .$$

After a second number Q of the average values are calculated, the Q second values are then averaged according to the equation (7) in the second average phase to obtain a gain error ε. The first average phase requires only a memory space storing P gain error estimates v[n], and the second average phase requires only a memory space storing Q average values. Thus, calculation of the gain error ε requires (P+Q) memory cells in total according to equation (7). Because the number (P+Q) of memory cells required by equation (7) is far less than the number N of memory cells required by equation (6), the equation (7) provided by the invention greatly reduces the memory space required for gain error estimation.

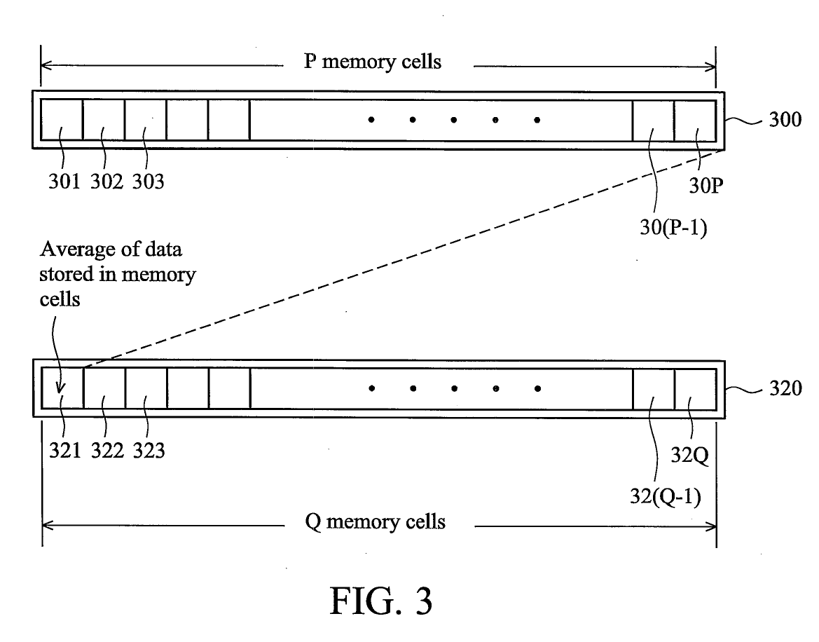

Referring to FIG. 3, two memories 300 and 320 of a pipelined ADC averaging gain error estimates with two phases according to the invention are shown. The first memory 300 comprises P memory cells, and the second memory 320 comprises Q memory cells, wherein a product of the numbers P and Q is equal to a number N of gain error estimates v[n] to be averaged in equation (3). The gain error correction module first calculates gain error estimates v[n] according to the equations (4) and (5). Every time a gain error estimate v[n] is calculated, the gain error estimate v[n] is stored in a memory cell of the memory 300. Thus, gain error estimates v[1], v[2], . . . , v[P−1], and v[P] are sequentially stored in memory cells 301, 302, . . . , 30(P−1), and 30P of the memory 300.

During the first average phase, every time when the first memory 300 stores P gain error estimates v[n], the P gain error estimates v[n] will be averaged to obtain an average value, and the P memory cells of the first memory 300 will be then cleared to store another P gain error estimates v[n]. The average values generated in the first average phase are then sequentially stored in the memory cells 321, 322, . . . , 32(Q−1), and 32Q of the second memory 320. During the second average phase, every time when the second memory 320 stores Q average values, the Q average values will be averaged to obtain a gain error ε, and the Q memory cells of the second memory 320 will be then cleared to store another Q average values generated during the first average phase. Thus, only (P+Q) memory cells are required in comparison with the (P×Q) memory cells required by the equation (6) provided for the conventional method. For example, if the number N of memory cells required by equation (6) is 2²⁰ and the numbers P and Q of memory cells of memories 300 and 320 are both 2¹⁰ (2¹⁰×2¹⁰=2²⁰), the number of required memory cells are reduced by (2²⁰−2¹¹).

Similarly, average of the gain error estimates v[n] can also be divided into more than two average phases. In other words, the average values

$$\frac{1}{P} {\sum }_{n = 1}^{P} v [ n ]$$

of equation (7) can be further divided into more than two phases. In one embodiment, a gain error correction module averages the gain error estimates in m average phases according to the following algorithm to calculate the gain error ε of the target stage:

$$ɛ = \frac{1}{{N}_{m}} {\sum }_{{k}_{m} = 1}^{{N}_{m}} {( … ( \frac{1}{{N}_{3}} {\sum }_{{k}_{3} = 1}^{{N}_{3}} {( \frac{1}{{N}_{2}} {\sum }_{{k}_{2} = 1}^{{N}_{2}} {( \frac{1}{{N}_{1}} {\sum }_{n = 1}^{{N}_{1}} v [ n ] )}_{{k}_{2}} )}_{{k}_{3}} ) … )}_{{k}_{m}} ; \qquad ( 8 )$$

wherein ε is the gain error, v[n] is a gain error estimate corresponding to a sample index n, m is a number of average phases, N₁, N₂, N₃, . . . , Nₘ are predetermined numbers, and a product of N₁, N₂, N₃, . . . , and Nₘ is equal to the number N of gain error estimates v[n] to be averaged in equation (3). In one embodiment, the numbers N₁, N₂, N₃, . . . , Nₘ are natural numbers. The gain error correction module first averages every N₁ gain error estimates v[n]in a first average phase to obtain a series of first average values

$$\frac{1}{{N}_{1}} {\sum }_{n = 1}^{{N}_{1}} v [ n ] .$$

The gain error correction module then averages every N₂ average values in a second average phase to obtain a series of second average values. The third, fourth, . . . , (m−1)-th and m-th average phases then accordingly averages average values generated in the prior average phases to obtain a series of average values thereof. The average values generated in the m-th average phase are a series of gain errors of the target stage. According to equation (8), calculation of a gain error ε requires only (N₁+N₂+ . . . +Nₘ₋₁+Nₘ) memory cells in total.

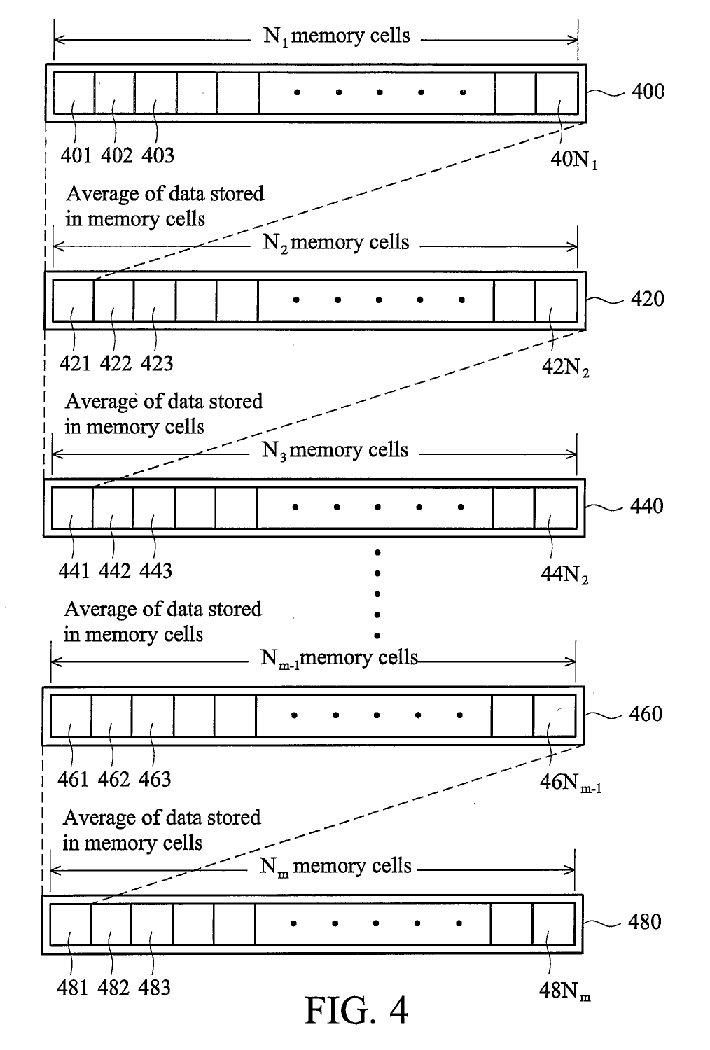

Referring to FIG. 4, a number m of memories 400, 420, . . . , 460, and 480 of a pipelined ADC averaging gain error estimates with m phases according to the invention is shown. The memories 400, 420, . . . , 460, and 480 respectively comprise N₁, N₂, N₃, . . . , Nₘ memory cells, wherein a product of the numbers N₁, N₂, N₃, . . . , Nₘ₋₁, and Nₘ is equal to a number N of gain error estimates v[n] to be averaged in equation (3). Every time a gain error correction module calculates a gain error estimate v[n] according to equations (4) and (5), the gain error estimate v[n] is stored in a memory cell of the memory 400.

During the first average phase, every time when the memory 400 stores N₁ gain error estimates v[n], the N₁ gain error estimates v[n] will be averaged to obtain a average value, and the memory cells of the memory 400 will be then cleared to store another N₁ gain error estimates v[n]. The average values generated in the first average phase are then sequentially stored in the memory cells 421, 422, . . . , 42(N₂−1), and 42N₂ of the memory 420. During the subsequent average phases, every time when the memories 420, . . . , 460, 480 stores N₂, . . . , Nₘ₋₁, and Nₘ average values, the N₂, . . . , Nₘ₋₁, and Nₘ average values will be averaged to obtain an average value to be stored in a memory cell of subsequent memories. Thus, the average values generated by the m-th average phase are a series of gain errors ε, and only (N₁+N₂+ . . . +Nₘ₋₁+Nₘ) memory cells are required in comparison with the (N×N₂× . . . ×Nₘ₋₁×Nₘ) memory cells required by the equation (6) provided by the conventional method.

After a gain error ε of the target stage is obtained, a gain error correction module calculates a digital conversion value Dₒᵤₜ of an analog input signal Vᵢₙ according to the gain error ε. In a conventional method, the gain error correction module calculates the digital conversion value Dₒᵤₜ according to the following algorithm:

$${D}_{out} = {d}_{o 1} + s + \frac{{d}_{o 2} \cdot {G}^{- 1} + {d}_{o 3} \cdot {G}^{- 2} + … + {d}_{o ( M - 1 )} \cdot {G}^{- ( M - 2 )} + {d}_{oM} \cdot {G}^{- ( M - 1 )}}{1 + ɛ} ; \qquad ( 9 )$$

wherein Dₒᵤₜ is the digital conversion value, s is the correction number applied to the target stage, dₒ₁ is the stage output value of the target stage, dₒ₂, dₒ₃, . . . , d_{o(M-1)}, and d_{oM} are digital output values of subsequent stages of the target stage, G is a predetermined gain value of the stages, M is a number of the stages, and ε is the gain error.

The equation (9), however, comprises a polynomial (1+ε) in the denominator. Thus, the gain error correction module must divide the digital output values dₒ₂, dₒ₃, . . . , d_{o(M-1)}, and d_{oM} by the polynomial (1+ε) of the gain error with a divider circuit to calculate the digital conversion value Dₒᵤₜ according to the conventional method. The divider circuit, however, has a complex circuit design and increases costs of the pipelined ADC. To reduce the pipelined ADC costs, a new algorithm is provided by the invention to calculate the digital conversion value Dₒᵤₜ without a divider circuit, as shown in the following:

Dₒᵤₜ=dₒ₁+s+(dₒ₂×G⁻¹+dₒ₃×G⁻²+ . . . +d_{oM}×G^{-(M-1)})·(1−ε+ε²−ε³+ . . . +(−1)^{k}ε^{k}). (10)

In the equation (10), the divisor (1+ε) in the equation (9) is replaced with a multiplier of a polynomial (1−ε+ε²−ε³+ . . . +(−1)^{k}ε^{k}) of the gain error ε wherein k is a predetermined number. Thus, the gain error correction module can calculate the digital conversion value Dₒᵤₜ according to the equation (10) by simply multiplying the digital output values dₒ₂, dₒ₃, . . . , d_{o(M-1)}, and d_{oM} by a polynomial of the gain error ε, and the costs of the pipelined ADC is reduced due to elimination of the divider circuit.

Before a system comprising an ADC operating according to the invention enters a sleep mode or is shut down, all of the values stored in memories of the ADC such as the memories 300 and 320 of FIG. 3 and memories 400, 420, 440, 460, and 480 may be saved in advance. When the system returns to a wakeup mode or is restarted, the saved values may be restored to the memories of the ADC, thus the ADC can then derive the digital conversion value Dₒᵤₜ from the restored values in the memories according to the invention.

The method provided by the invention is suitable for estimating gain errors of any stages selected from a plurality of stages of an ADC. In addition, although the method provided by the invention is illustrated with a pipelined ADC, because a cyclic ADC has a similar structure to that of a pipelined ADC, except that the stages of a cyclic ADC may share a common circuit, the method provided by the invention is also applicable to a cyclic ADC.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for gain error estimation for an analog-to-digital converter, wherein the analog-to-digital converter comprises a plurality of stages, the method comprising:
correlating a series of correction numbers applied to a target stage selected from the stages with a series of calculation values calculated according to digital output values of the stages to generate a series of gain error estimates;
averaging every first number of the gain error estimates to obtain a series of first average values; and
averaging every second number of the first average values to obtain a series of gain errors of the target stage.

2. The method as claimed in claim 1, wherein averaging of every first number of gain error estimates comprises:
averaging every third number of the gain error estimates to obtain a series of second average values; and
averaging every fourth number of the second average values to obtain the series of first average values;
wherein a product of the third number and the fourth number is equal to the first number.

3. The method as claimed in claim 1, wherein the method further comprises:
saving the gain error estimates and the first average values before a system comprising the analog-to-digital converter enters a sleep mode or is shut down; and
restoring the gain error estimates and the first average values for further gain error estimation of the analog-to-digital converter after the system returns to a wakeup mode or is restarted.

4. The method as claimed in claim 1, wherein the first average values are obtained according to the following algorithm:
$$p = \frac{1}{{N}_{m}} {\sum }_{{k}_{m} = 1}^{{N}_{m}} {( … ( \frac{1}{{N}_{3}} {\sum }_{{k}_{3} = 1}^{{N}_{3}} {( \frac{1}{{N}_{2}} {\sum }_{{k}_{2} = 1}^{{N}_{2}} {( \frac{1}{{N}_{1}} {\sum }_{n = 1}^{{N}_{1}} v [ n ] )}_{{k}_{2}} )}_{{k}_{3}} ) … )}_{{k}_{m}} ;$$
wherein p is the first average value, n is a sample index, v[n] is the gain error estimate, N₁, N₂, N₃, . . . Nₘ are numbers, and a product of N₁, N₂, N₃, . . . , and Nₘ is equal to the first number.

5. The method as claimed in claim 4, wherein the numbers N₁, N₂, N₃, . . . Nₘ are natural numbers.

6. The method as claimed in claim 1, wherein the calculation values are calculated according to the following algorithm:
u[n]=dₒ₁[n]+s[n]+dₒ₂[n]×G⁻¹+dₒ₃[n]×G⁻²+ . . . +d_{oM}[n]×G^{-(M-1)};
wherein u[n] is the calculation value, n is a sample index, s[n] is the correction number, M is a number of the stages, G is a predetermined gain of the stages, dₒ₁ is the digital output value of the target stage, and dₒ₂[n], dₒ₃[n], . . . , d_{oM}[n] are the digital output values of the stages subsequent to the target stage.

7. The method as claimed in claim 6, wherein the gain error estimates are generated according to the following algorithm:
$$v [ n ] = \frac{u [ n ]}{s [ n ]} ;$$
wherein v[n] is the gain error estimate, n is a sample index, s[n] is the correction number, and u[n] is the corresponding calculation value.

8. The method as claimed in claim 1, wherein the analog-to-digital converter is a pipelined analog-to-digital converter.

9. The method as claimed in claim 1, wherein the analog-to-digital converter is a cyclic analog-to-digital converter.

10. An analog-to-digital converter, comprising:
a plurality of stages, respectively generating a series of digital output values, wherein one of the stages is selected as a target stage for gain error estimation and processed with a series of correction numbers; and
a gain error correction module, calculating a series of calculation values according to the digital output values of the stages, correlating the series of correction numbers with the series of calculation values to generate a series of gain error estimates, averaging every first number of the gain error estimates to obtain a series of first average values, and averaging every second number of the first average values to obtain a series of gain errors of the target stage.

11. The analog-to-digital converter as claimed in claim 10, wherein the gain error correction module averages every third number of the gain error estimates to obtain a series of second average values, and averages every fourth number of the second average values to obtain the series of first average values, wherein a product of the third number and the fourth number is equal to the first number.

12. The analog-to-digital converter as claimed in claim 10, wherein the gain error correction module averages every fifth number of the first average values to obtain a series of third average values, and averages every sixth number of the third average values to obtain the series of gain errors, wherein a product of the fifth number and the sixth number is equal to the second number.

13. The analog-to-digital converter as claimed in claim 10, wherein the gain error correction module generates the first average values according to the following algorithm:
$$p = \frac{1}{{N}_{m}} {\sum }_{{k}_{m} = 1}^{{N}_{m}} {( … ( \frac{1}{{N}_{3}} {\sum }_{{k}_{3} = 1}^{{N}_{3}} {( \frac{1}{{N}_{2}} {\sum }_{{k}_{2} = 1}^{{N}_{2}} {( \frac{1}{{N}_{1}} {\sum }_{n = 1}^{{N}_{1}} v [ n ] )}_{{k}_{2}} )}_{{k}_{3}} ) … )}_{{k}_{m}} ;$$
wherein p is the first average value, n is a sample index, v[n] is the gain error estimate, N₁, N₂, N₃, . . . Nₘ are numbers, and a product of N₁, N₂, N₃, . . . , and Nₘ is equal to the first number.

14. The analog-to-digital converter as claimed in claim 13, wherein the numbers N₁, N₂, N₃, . . . , Nₘ are natural numbers.

15. The analog-to-digital converter as claimed in claim 10, wherein the gain error correction module calculates the calculation values according to the following algorithm:
u[n]=dₒ₁[n]+s[n]+dₒ₂[n]×G⁻¹+dₒ₃[n]×G⁻²+ . . . +d_{oM}[n]×G^{-(M-1)};
wherein u[n] is the calculation value, n is a sample index, s[n] is the correction number, M is a number of the stages, G is a predetermined gain of the stages, dₒ₁ is the digital output value of the target stage, and dₒ₂[n], dₒ₃[n], . . . , d_{oM}[n] are the digital output values of the stages subsequent to the target stage.

16. The analog-to-digital converter as claimed in claim 15, wherein the gain error correction module generates the gain error estimates according to the following algorithm:
$$v [ n ] = \frac{u [ n ]}{s [ n ]} ;$$
wherein v[n] is the gain error estimate, n is a sample index, s[n] is the correction number, and u[n] is the corresponding calculation value.

17. The analog-to-digital converter as claimed in claim 10, wherein the analog-to-digital converter is a pipelined analog-to-digital converter or a cyclic analog-to-digital converter.

18. A method for gain error correction in an analog-to-digital converter, wherein the analog-to-digital converter receives an analog input signal and comprises a plurality of stages, the method comprising:
estimating a gain error of a target stage selected from the stages; and
deriving a digital conversion value of the analog input signal from digital output values of the stages by multiplying the digital output values by a polynomial of the gain error.

19. The method as claimed in claim 18, wherein coefficients of the polynomial are (−1)^{k}, wherein k is a degree of the gain error in a monomial of the polynomial.

20. The method as claimed in claim 18, wherein the polynomial is (1−ε+ε²−ε³+ . . . +(−1)^{k}ε^{k}), wherein ε is the gain error and k is a predetermined number.

21. The method as claimed in claim 18, wherein the digital conversion value is derived according to the following algorithm:
dₒᵤₜ=dₒ₁+s+(dₒ₂×G⁻¹+dₒ₃×G⁻²+ . . . +d_{oM}×G^{-(M-1)})·(1−ε+ε²−ε³+ . . . +(−1)^{k}ε^{k})
wherein dₒᵤₜ is the digital conversion value, dₒ₁ is the digital output value of the target stage, s is a correction number applied to the target stage, dₒ₂, dₒ₃, . . . , d_{oM} are the digital output values of the stages subsequent to the target stage, G is a predetermined gain of the stages, M is a number of the stages, and ε is the gain error.

22. The method as claimed in claim 18, wherein the gain error is estimated according to the following algorithm:
$$ɛ = \frac{1}{N} {\sum }_{n = 1}^{N} \frac{{d}_{o 1} [ n ] + s [ n ] + {d}_{o 2} [ n ] {G}^{- 1} + {d}_{o 3} {G}^{- 2} + … + {d}_{oM} [ n ] {G}^{- ( M - 1 )}}{s [ n ]} ;$$
wherein ε is the gain error, n is a sample index, dₒ₁ is the digital output value of the target stage, s is a correction number applied to the target stage, M is a number of the stages, dₒ₁ is the digital output value of the target stage, dₒ₂, dₒ₃, . . . , d_{oM} are the digital output values of the stages subsequent to the target stage, G is a predetermined gain of the stages, and N is a number of samples.

23. The method as claimed in claim 18, wherein the analog-to-digital converter is a pipelined analog-to-digital converter or a cyclic analog-to-digital converter.
